(19) United States
(12) Patent Application Publication
(10) Pub. No.: US 2025/0202226 A1
(43) Pub. Date: Jun. 19, 2025

(54) EMP POWER FILTER

(71) Applicant: ELECTRONICS AND TELECOMMUNICATIONS RESEARCH INSTITUTE, Daejeon (KR)

(72) Inventors: Ui-Jung KIM, Daejeon (KR); Jin-Ha YOO, Daejeon (KR); Kwang-Uk CHU, Daejeon (KR); Dae-Heon LEE, Daejeon (KR); Up NAMKOONG, Daejeon (KR)

(21) Appl. No.: 18/897,594

(22) Filed: Sep. 26, 2024

(30) Foreign Application Priority Data
Dec. 19, 2023 (KR) 10-2023-0185525

(51) Int. Cl. H02H 9/04; H03H 7/01

(52) U.S. Cl. CPC H02H 9/04; H03H 7/0115

(57) ABSTRACT

Disclosed herein is an Electromagnetic Pulse (EMP) power filter. The EMP power filter may include a varistor connected between the input terminal of a power line and a ground line, first to fourth inductors connected in series from the input terminal of the power line, a first feedthrough capacitor connected between the first inductor and the second inductor, a second feedthrough capacitor connected between the third inductor and the fourth inductor, and a dedicated surge protection circuit module having a first end connected between the second inductor and the third inductor and a second end connected to the ground line.

### CROSS REFERENCE TO RELATED APPLICATION

This application claims the benefit of Korean Patent Application No. 10-2023-0185525, filed Dec. 19, 2023, which is hereby incorporated by reference in its entirety into this application.

### BACKGROUND OF THE INVENTION

### 1. Technical Field

The disclosed embodiment relates to an Electromagnetic Pulse (EMP) power filter used for electromagnetic shielded facilities and the like.

### 2. Description of Related Art

A power filter is a product that is used in order to block a high-power surge and an external noise signal delivered through a power line.

Such a power filter basically has the configuration of a low-pass filter circuit in order to block signals other than signals of a power frequency (50˜60 Hz in the case of AC), and may alternatively include a surge protection device (SPD) in order to protect against high-power surges.

Representative surge protection devices (SPDs) include Metal Oxide Varistors (MOVs), Gas Discharge Tubes (GDTs), etc., but most power-line filters use MOVs having a fast response speed and a low residual voltage.

A power filter is installed at the entry point of a power line and used to prevent external signals from flowing into electronic equipment or facilities.

Unlike power filters for electronic products, a filter for a facility has a separate housing and is installed at a power input stage, thereby preventing external noise signals from flowing into the facility and being used to supply power to electronic devices in the facility.

Particularly, EMP power filters are used to supply power to electromagnetic shielded facilities, which are shielded from external electromagnetic waves, and devices (SPDs) for blocking high-power surges as well as noise delivered through a power line are also installed together.

Tests for measuring performance of the filters include insertion loss measurement for checking the blocking of frequencies out of a frequency band in use and a Pulse Current Injection (PCI) test for checking the performance of the blocking of external surge signals. Also, a plurality of power filters may be installed and operated in a single facility when the facility uses high power.

A power filter is designed as an L-C low-pass filter structure including inductors and capacitors in order to block wideband high-frequency noise excluding a commercial power frequency. However, when the capacity of current supplied to a power line increases, the volumes and weights of the inductors and capacitors used for production of the power filter increase, which results in an increase in the volume and weight of the power filter. Also, as the wideband high-frequency noise blocking performance of a product is higher, the volume and weight of the product increase. This is because more components (inductors and capacitors) are used to produce the filter.

For this reason, the volume and weight of the power filter generally increase as the current capacity or the noise blocking performance of the product is higher.

### SUMMARY OF THE INVENTION

An object of the disclosed embodiment is to design a power filter, which is used for blocking a surge and external noise delivered through a power line, to have a simplified configuration, thereby designing and producing a power filter that is lighter and smaller than an existing product.

An Electromagnetic Pulse (EMP) power filter according to an embodiment may include a varistor connected between the input terminal of a power line and a ground line, first to fourth inductors connected in series from the input terminal of the power line, a first feedthrough capacitor connected between the first inductor and the second inductor, a second feedthrough capacitor connected between the third inductor and the fourth inductor, and a dedicated surge protection circuit module having a first end connected between the second inductor and the third inductor and a second end connected to the ground line.

Here, the dedicated surge protection circuit module may include a low-frequency signal blocking unit for attenuating the magnitude of a power signal applied to the power line, a surge signal switching unit for delivering a surge signal equal to or greater than a predetermined threshold through the ground line, and a switching element protection unit for limiting a voltage and a current input to the surge signal switching unit.

Here, the low-frequency signal blocking unit may include a first capacitor having a first end connected to the power line and a second capacitor having a first end connected to the power line.

Here, the surge signal switching unit may include a power transistor connected between the output terminal of the switching element protection unit, the second end of the second capacitor, and the ground line.

Here, the power transistor may be implemented as any one of an Insulated Gate Bipolar Transistor (IGBT), a Bipolar Junction Transistor (BJT), and a Field Effect Transistor (FET).

Here, the surge signal switching unit may further include a third capacitor and a first resistor connected in parallel between the second end of the second capacitor and the ground line.

Here, the surge signal switching unit may further include a third capacitor and a first resistor sequentially connected in series between the second end of the second capacitor and the ground line.

Here, the switching element protection unit may include a fourth capacitor connected to the second end of the first capacitor and the ground line, a first diode connected to the second end of the first capacitor, a second resistor and a Transient Voltage Suppressor (TVS) diode connected in parallel between the second end of the first diode and the ground line, and a third resistor connected between the second end of the first diode and the power transistor.

Here, the EMP power filter according to an embodiment may further include an additional dedicated surge protection circuit module having a first end connected between the third inductor and the second feedthrough capacitor and a second end connected to the ground line.

An EMP power filter according to an embodiment may include a first varistor connected between the input terminal of a first power line and a ground line, first to fourth inductors connected in series from the input terminal of the first power line, a first feedthrough capacitor connected between the first inductor and the second inductor, a second feedthrough capacitor connected between the third inductor and the fourth inductor, a first dedicated surge protection circuit module having a first end connected between the second inductor and the third inductor and a second end connected to the ground line, a second varistor connected between the input terminal of a second power line and the ground line, fifth to eighth inductors connected in series from the input terminal of the second power line, a third feedthrough capacitor connected between the fifth inductor and the sixth inductor, a fourth feedthrough capacitor connected between the seventh inductor and the eighth inductor, a second dedicated surge protection circuit module having a first end connected between the sixth inductor and the seventh inductor and a second end connected to the ground line, and a capacitor and a resistor connected in parallel, each having a first end connected between the first feedthrough capacitor and the second inductor and a second end connected between the third feedthrough capacitor and the sixth inductor.

Here, at least one of the first dedicated surge protection circuit module, or the second dedicated surge protection circuit module, or a combination thereof may include a low-frequency signal blocking unit for attenuating the magnitude of a power signal applied to the power line, a surge signal switching unit for delivering a surge signal equal to or greater than a predetermined threshold through the ground line, and a switching element protection unit for limiting a voltage and a current input to the surge signal switching unit.

Here, the low-frequency signal blocking unit may include a first capacitor having a first end connected to the power line and a second capacitor having a first end connected to the power line.

Here, the surge signal switching unit may include a power transistor connected between the output terminal of the switching element protection unit, the second end of the second capacitor, and the ground line.

Here, the power transistor may be implemented as any one of an Insulated Gate Bipolar Transistor (IGBT), a Bipolar Junction Transistor (BJT), and a Field Effect Transistor (FET).

Here, the surge signal switching unit may further include a third capacitor and a first resistor connected in parallel between the second end of the second capacitor and the ground line.

Here, the surge signal switching unit may further include a third capacitor and a first resistor sequentially connected in series between the second end of the second capacitor and the ground line.

Here, the switching element protection unit may include a fourth capacitor connected to the second end of the first capacitor and the ground line, a first diode connected to the second end of the first capacitor, a second resistor and a TVS diode connected in parallel between the second end of the first diode and the ground line, and a third resistor connected between the second end of the first diode and the power transistor.

A dedicated high-power surge protection circuit device according to an embodiment is connected between elements constituting an L-C filter of an EMP power filter, and may include a low-frequency signal blocking unit for attenuating the magnitude of a power signal applied to a power line, a surge signal switching unit for delivering a surge signal equal to or greater than a predetermined threshold through a ground line, and a switching element protection unit for limiting a voltage and a current input to the surge signal switching unit.

Here, the low-frequency signal blocking unit may include a first capacitor and a second capacitor, each having a first end connected to the power line.

Here, the surge signal switching unit may include a power transistor connected between the output terminal of the switching element protection unit, the second end of the second capacitor, and the ground line and a third capacitor and a first resistor connected in parallel or series between the second end of the second capacitor and the ground line. Here, the power transistor may be implemented as any one of an Insulated Gate Bipolar Transistor (IGBT), a Bipolar Junction Transistor (BJT), and a Field Effect Transistor (FET).

Here, the switching element protection unit may include a fourth capacitor connected to the second end of the first capacitor and the ground line, a first diode connected to the second end of the first capacitor, a second resistor and a TVS diode connected in parallel between the second end of the first diode and the ground line, and a third resistor connected between the second end of the first diode and the power transistor.

### BRIEF DESCRIPTION OF THE DRAWINGS

The above and other objects, features, and advantages of the present disclosure will be more clearly understood from the following detailed description taken in conjunction with the accompanying drawings, in which:

FIG. 1 is a circuit diagram of a general EMP power filter;

FIG. 2 is a circuit diagram of an EMP power filter according to an embodiment;

FIG. 3 is a functional block diagram of a dedicated surge protection circuit module according to an embodiment;

FIG. 4 is a circuit diagram of a dedicated surge protection circuit module according to a first embodiment;

FIG. 5 is a circuit diagram of a dedicated surge protection circuit module according to a second embodiment;

FIG. 6 is a circuit diagram of an EMP power filter according to another embodiment;

FIG. 7 is a circuit diagram of an EMP power filter according to a further embodiment;

FIG. 8 is an exemplary view of an input signal used for a PCI test for evaluating the performance of an EMP power filter according to an embodiment;

FIG. 9 is an exemplary view of a simulation test result of a residual current characteristic in a PCI test for an EMP power filter according to an embodiment;

FIG. 10 is an exemplary view of a simulation test result of an insertion loss characteristic for an EMP power filter according to an embodiment;

FIG. 11 is an exemplary view of a simulation test result of a leakage current of a commercial EMP power filter; and

FIG. 12 is an exemplary view of a simulation test result of a leakage current of an EMP power filter according to an embodiment.

### DESCRIPTION OF THE PREFERRED EMBODIMENTS

The advantages and features of the present disclosure and methods of achieving them will be apparent from the following exemplary embodiments to be described in more detail with reference to the accompanying drawings. However, it should be noted that the present disclosure is not limited to the following exemplary embodiments, and may be implemented in various forms. Accordingly, the exemplary embodiments are provided only to disclose the present disclosure and to let those skilled in the art know the category of the present disclosure, and the present disclosure is to be defined based only on the claims. The same reference numerals or the same reference designators denote the same elements throughout the specification.

It will be understood that, although the terms “first,” “second,” etc. may be used herein to describe various elements, these elements are not intended to be limited by these terms. These terms are only used to distinguish one element from another element. For example, a first element discussed below could be referred to as a second element without departing from the technical spirit of the present disclosure.

The terms used herein are for the purpose of describing particular embodiments only and are not intended to limit the present disclosure. As used herein, the singular forms are intended to include the plural forms as well, unless the context clearly indicates otherwise. It will be further understood that the terms “comprises,” “comprising,”, “includes” and/or “including,” when used herein, specify the presence of stated features, integers, steps, operations, elements, and/or components, but do not preclude the presence or addition of one or more other features, integers, steps, operations, elements, components, and/or groups thereof.

Unless differently defined, all terms used herein, including technical or scientific terms, have the same meanings as terms generally understood by those skilled in the art to which the present disclosure pertains. Terms identical to those defined in generally used dictionaries should be interpreted as having meanings identical to contextual meanings of the related art, and are not to be interpreted as having ideal or excessively formal meanings unless they are definitively defined in the present specification.

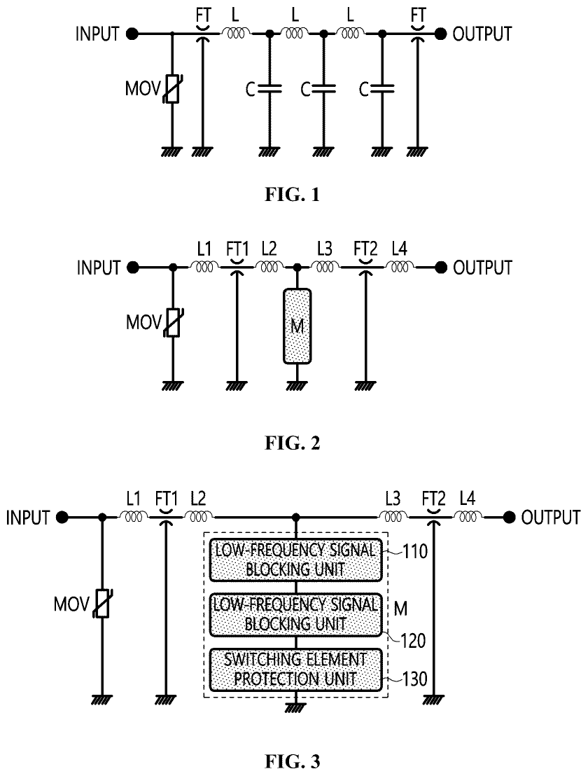

FIG. 1 is a circuit diagram of a general EMP power filter.

Referring to FIG. 1, a surge protection device MOV for blocking high-power surges is connected to the input terminal INPUT of a general EMP power filter. Also, the EMP power filter has an L-C low-pass filter structure including multiple inductors L connected in series and multiple capacitors C connected in parallel between the multiple inductors L. Also, feedthrough capacitors FT with good high-frequency characteristics are connected to the input terminal INPUT and output terminal OUTPUT of the EMP power filter.

In the EMP power filter configured as described above, a high-power surge signal induced on a power line is attenuated first through the surge protection device MOV, and is then gradually attenuated while passing through the L-C low pass filter, whereby the surge signal reduced to be equal to or less than a certain level is output to the output terminal OUTPUT.

Because a general EMP power filter is designed and produced as a low-pass filter structure including inductors and capacitors, as described above, when it is designed, the numbers of inductors and capacitors may be increased or the capacity of each of the elements may be adjusted in order to satisfy a standard for wideband noise cancellation performance. However, when the number of elements and the capacity of the elements is increased in consideration of the performance, the volume and weight of the EMP power filter are also increased.

Meanwhile, in an electromagnetic shielded facility, it is necessary to install multiple power filters in consideration of the amount of power to be consumed in the facility or the supply of power for each use. For example, a power filter for each use may be installed in order to separately supply power to air conditioners, lighting, general devices, servers, and computation equipment.

Accordingly, a large space is required in order to install multiple power filters, and it is necessary to make power filters lighter or smaller in consideration of the space in which the power filters are to be installed.

Also, the capacity of capacitors C connected in parallel between a power line and a ground line determines a leakage current consumed through the ground line rather than being delivered to the actual load. Therefore, when the capacity of the capacitors is increased in order to improve the surge suppression performance, the leakage current may also increase.

Here, because the current leaking through the ground line not only degrades the power usage efficiency but also causes a safety accident, it is desirable that a power filter should be designed and produced to decrease the leakage current.

Therefore, an embodiment proposes a small and lightweight power filter by including a circuit module dedicated to blocking a high-power surge in the power filter.

FIG. 2 is a circuit diagram of an EMP power filter according to an embodiment.

Referring to FIG. 2, an EMP power filter according to an embodiment may be configured such that a dedicated surge protection circuit module M is connected between elements constituting an L-C filter.

Here, the EMP power filter may include a varistor (Metal Oxide Varistor (MOV)) connected between the input terminal INPUT of a power line PWL and a ground line.

Here, the MOV is a nonlinear device, the resistance of which is very high when the absolute value of the voltage across the terminals is less than a specific value, but the resistance of which rapidly decreases when the absolute value is equal to or greater than the specific value. Such a varistor MOV is located before the L-C filter and configures an earth circuit by discharging the overvoltage flowing from the input terminal INPUT of the power line, thereby protecting the L-C filter circuit.

Here, the L-C filter may include first to fourth inductors L1 to L4 connected in series from the input terminal INPUT of the power line, a first feedthrough capacitor FT1 connected between the first inductor L1 and the second inductor L2, and a second feedthrough capacitor FT2 connected between the third inductor L3 and the fourth inductor L4.

Here, the first feedthrough capacitor FT1 and the second feedthrough capacitor FT2 may be installed by passing through the wall of the housing containing the EMP power filter.

According to an embodiment, the dedicated surge protection circuit module M may be configured such that the first end thereof is connected between the second inductor L2 and the third inductor L3 and the second end thereof is connected to the

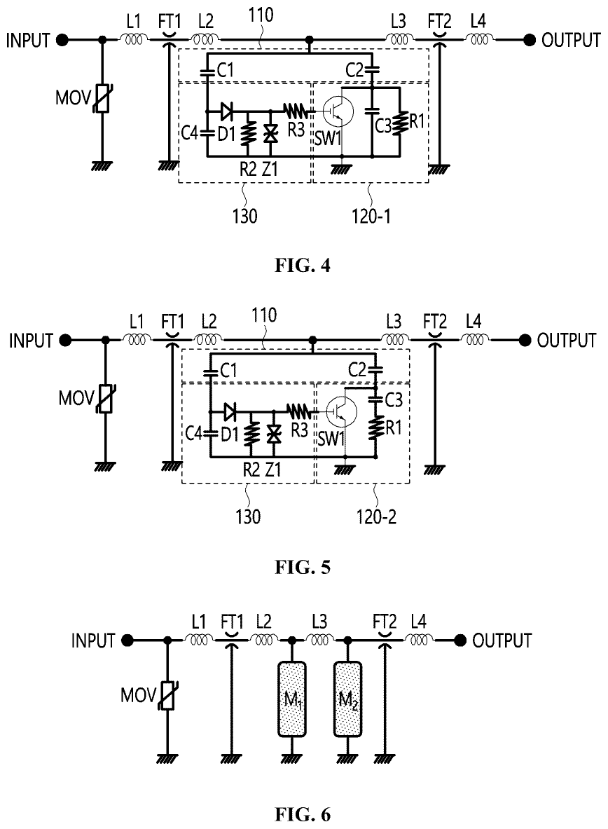

FIG. 3 is a functional block diagram of a dedicated surge protection circuit module according to an embodiment, FIG. 4 is a circuit diagram of a dedicated surge protection circuit module according to a first embodiment, and FIG. 5 is a circuit diagram of a dedicated surge protection circuit module according to a second embodiment.

Referring to FIG. 3, a dedicated surge protection circuit module M according to an embodiment may include a low-frequency signal blocking unit 110, a surge signal switching unit 120, and a switching element protection unit 130.

The low-frequency signal blocking unit 110 may attenuate the magnitude of a power signal applied to a power line. That is, it attenuates the magnitude of a commercial power signal component having a frequency of 60 Hz, which is applied to the power line.

Specifically, the low-frequency signal blocking unit 110 may include a first capacitor C1 and a second capacitor C2, each having a first end connected to the power line, as illustrated in FIG. 4 and FIG. 5.

The surge signal switching unit 120 may deliver a surge signal equal to or greater than a predetermined threshold through a ground line.

Specifically, according to a first embodiment, the surge signal switching unit 120-1 may include a power transistor SW1 connected between the output terminal of the switching element protection unit, the second end of the second capacitor, and the ground line and a third capacitor C3 and a first resistor R1 that are connected in parallel between the second end of the second capacitor and the ground line, as illustrated in FIG. 4.

Meanwhile, according to a second embodiment, the surge signal switching unit 120-2 may include a power transistor SW1 connected between the output terminal of the switching element protection unit, the second end of the second capacitor, and the ground line and a third capacitor C3 and a first resistor R1 that are sequentially connected in series between the second end of the second capacitor and the ground line, as illustrated in FIG. 5.

Accordingly, when a surge signal equal to or greater than a predetermined threshold is applied to the power line and is input through the first capacitor C1 and second capacitor C2 of the low-frequency signal blocking unit 110, the power transistor SW1 is switched on, whereby the surge signal is delivered to the ground line.

Here, the power transistor SW1 may be implemented as any one of an Insulated Gate Bipolar Transistor (IGBT), a Bipolar Junction Transistor (BJT), a Field Effect Transistor (FET), and a thyristor, each having voltage and current capacity to accommodate a high-power surge signal.

For example, when the power transistor SW1 is an IGBT, the gate thereof may be connected to the second end of a third resistor R3, the collector thereof may be connected to the second end of the second capacitor C2, and the emitter thereof may be connected to the ground line.

Also, considering the sensitivity of the response to a high-power surge signal input to the EMP power filter, as the operation start delay time is shorter, it may be more advantageous to the power transistor SW1. For example, the operation start delay time may be equal to or less than 100 ns.

The switching element protection unit 130 may limit the voltage and current input to the surge signal switching unit 120.

Specifically, the switching element protection unit 130 may include a fourth capacitor C4 connected to the second end of the first capacitor C1 and the ground line, a first diode D1 connected to the second end of the first capacitor C1, a second resistor R2 and a Transient Voltage Suppressor (TVS) diode Z1 that are connected in parallel between the second end of the first diode D1 and the ground line, and a third resistor R3 connected between the second end of the first diode D1 and the power transistor SW1, as illustrated in FIG. 4 and FIG. 5.

Here, the TVS diode Z1 is a protection element for preventing the voltage input to the power transistor SW1 from increasing to be equal to or greater than a certain level.

Also, the first diode D1 is a rectifier element for inducing the surge signal input from the power line to flow unidirectionally.

When only commercial power that does not include a surge signal is input to the EMP power filter including the dedicated surge protection circuit module M configured as described above, the surge signal switching unit 120 does not operate, so all signals may be delivered to the output terminal OUTPUT.

Conversely, when a signal including a surge signal is input to the EMP power filter, the power signal is attenuated in the low-frequency signal blocking unit 110, and only the surge signal is delivered to the ground line through the surge signal switching unit 120.

The EMP power filter including the dedicated surge protection circuit module M according to the above-described embodiment has an advantage in which each component of the L-C filter can be designed to have lower capacity than the existing one.

This is because the dedicated surge protection circuit moule M can effectively attenuate a high-power surge signal. Accordingly, components having lower capacity than the existing components may be selected as components to be used for design of the L-C filter structure.

Particularly, because the volume and weight of an inductor L rapidly increase with an increase in the capacity, when a component having lower capacity is selected, this may be advantageous to reducing the volume and weight of the EMP power filter.

FIG. 6 is a circuit diagram of an EMP power filter according to another embodiment.

Referring to FIG. 6, an EMP power filter according to another embodiment may be configured such that two dedicated surge protection circuit modules M1 and M2 are connected between elements constituting the L-C filter of the EMP power filter.

Here, the EMP power filter may include a varistor MOV connected between the input terminal of a power line and a ground line.

Here, the L-C filter may include first to fourth inductors L1 to L4 connected in series from the input terminal of the power line, a first feedthrough capacitor FT1 connected between the first inductor L1 and the second inductor L2, and a second feedthrough capacitor FT2 connected between the third inductor L3 and the fourth inductor L4.

According to another embodiment, the first dedicated surge protection circuit module M1 may be configured such that the first end thereof is connected between the second inductor L2 and third inductor L3 and the second end thereof is connected to the ground line, and the second dedicated surge protection circuit module M2 may be configured such that the first end thereof is connected between the third inductor L3 and the second feedthrough capacitor FT2 and the second end thereof is connected to the

Here, the first dedicated surge protection circuit module M1 and the second dedicated surge protection circuit module M2 may be configured in the same manner as illustrated in FIG. 3, FIG. 4 and FIG. 5. However, according to need, different components may be applied to the detailed configuration of the first dedicated surge protection circuit module M1 and the second dedicated surge protection circuit module M2.

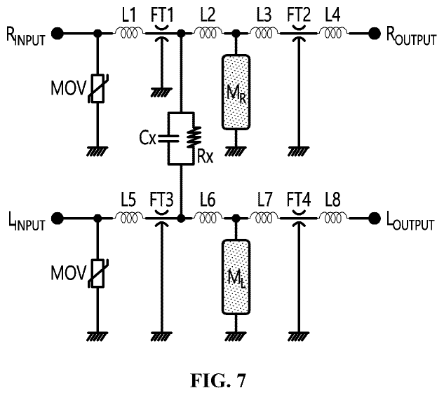

FIG. 7 is a circuit diagram of an EMP power filter according to a further embodiment.

Referring to FIG. 7, an EMP power filter according to a further embodiment may be configured such that each of two dedicated surge protection circuit modules M_{R} and M_{L} is connected between elements constituting an L-C filter in each of a first power line R and a second power line L. Also, the first power line R and the second power line L may be connected through a capacitor C_{X}.

Specifically, the EMP power filter according to a further embodiment may include a first varistor MOV connected between the input terminal of the first power line and a ground line, first to fourth inductors L1 to L4 connected in series from the input terminal R_{INPUT} of the first power line, a first feedthrough capacitor FT1 connected between the first inductor L1 and the second inductor L2, a second feedthrough capacitor FT2 connected between the third inductor L3 and the fourth inductor L4, the first dedicated surge protection circuit module M_{R} having a first end connected between the second inductor L2 and the third inductor L3 and a second end connected to the ground line, a second varistor MOV connected between the input terminal L_{INPUT} of the second power line and the ground line, fifth to eighth inductors L5 to L8 connected in series from the input terminal of the second power line, a third feedthrough capacitor FT3 connected between the fifth inductor L5 and the sixth inductor L6, a fourth feedthrough capacitor FT4 connected between the seventh inductor L7 and the eighth inductor L8, the second dedicated surge protection circuit module M_{L} having a first end connected between the sixth inductor L6 and the seventh inductor L7 and a second end connected to the ground line, and a capacitor C_{X} and a resistor R_{X} that are connected in parallel, each having a first end connected between the first feedthrough capacitor FT1 and the second inductor L2 and a second end connected between the third feedthrough capacitor FT3 and the sixth inductor L6.

Here, the first dedicated surge protection circuit module M_{R} and the second dedicated surge protection circuit module M_{L} may be configured in the same manner as illustrated in FIG. 3, FIG. 4 and FIG. 5. However, according to need, different components may be applied to the detailed configuration of the first dedicated surge protection circuit module M_{R} and the second dedicated surge protection circuit module M_{L}.

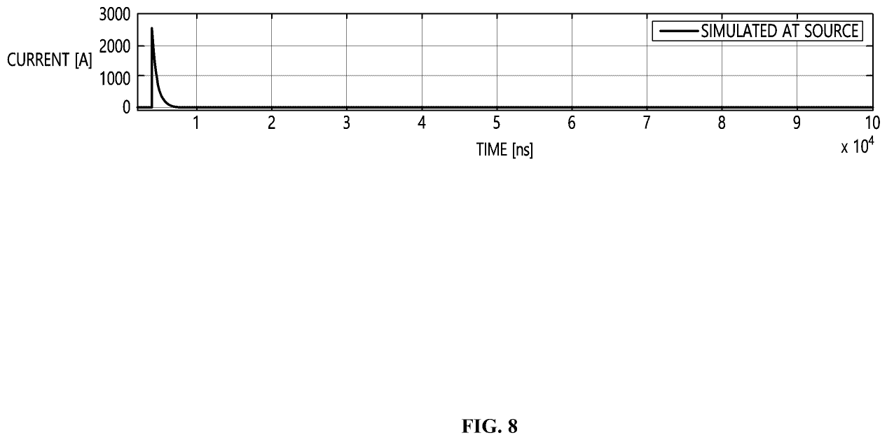

FIG. 8 is an exemplary view of an input signal used for a PCI test for evaluating the performance of an EMP power filter according to an embodiment.

Referring to FIG. 8, a Pulse Current Injection (PCI) test is a test for evaluating the surge suppression performance of an EMP power filter.

A test procedure and performance evaluation criteria are specified in MIL-STD-188-125-1, which is a U. S. military standard. This standard specifies that, when an input signal of up to 2.5 kA is applied in the state in which a 2Ω resistor is connected to the terminal of each power line of a power filter, the output residual current must be equal to or lower than 10 A.

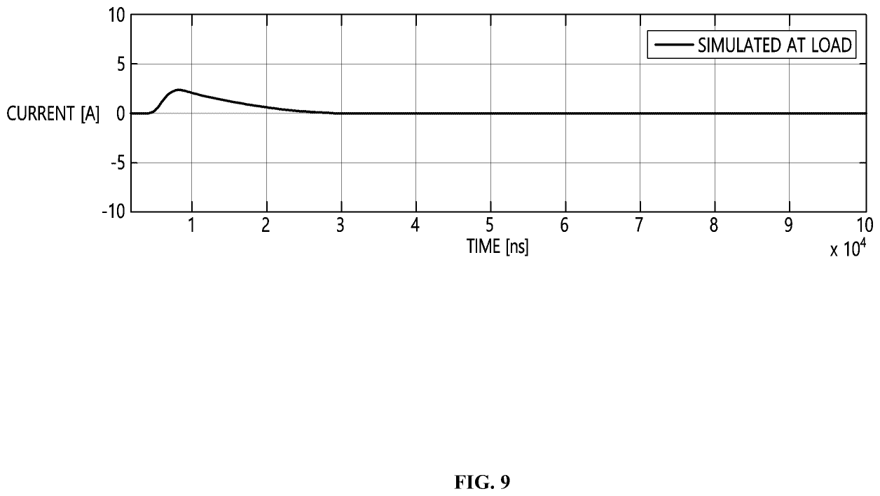

FIG. 9 is an exemplary view of a simulation test result of a residual current characteristic in a PCI test for an EMP power filter according to an embodiment.

Referring to FIG. 9, when a current of 2.5 kA is input to the designed EMP power filter, a residual current of about 4 A is output, and this is lower than 10 A that is presented as a performance criterion in the MIL standard.

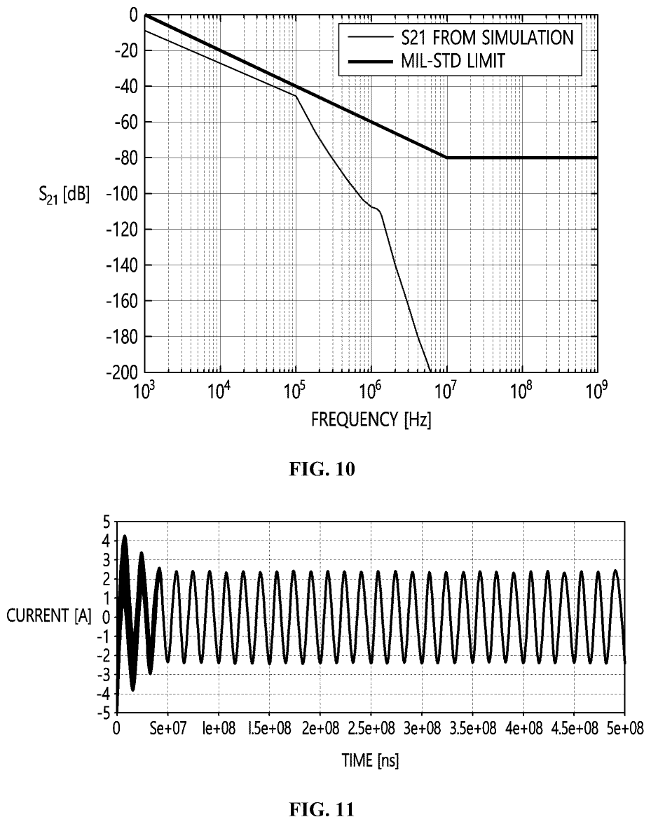

FIG. 10 is an exemplary view of a simulation test result of an insertion loss characteristic for an EMP power filter according to an embodiment.

MIL-STD-188-125-1 does not present the insertion loss characteristic of a power filter as an evaluation criterion. However, due to the characteristic of a filter connected to an electromagnetic shielding structure, an electromagnetic shielding characteristic equal to or higher than that of the shielding structure is generally proposed in order to secure an electromagnetic blocking characteristic of the filter itself.

For this reason, commercial power filters also present the insertion loss characteristic as a performance indicator.

In FIG. 10, the solid line is a line indicating a shielding performance criterion for an electromagnetic shielding structure presented in the MIL standard, and it can be seen that the insertion loss of the power filter according to an embodiment satisfies the criterion across the entire frequency band (10 kHz to 1 GHz).

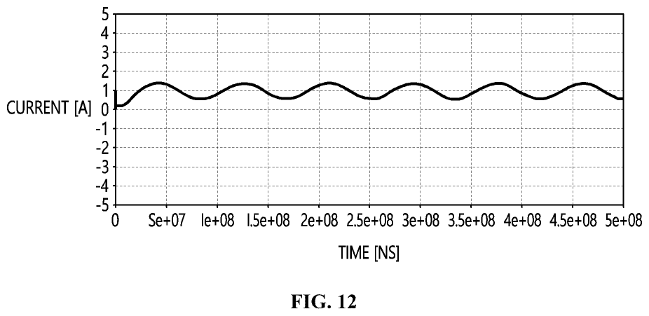

FIG. 11 is an exemplary view of a simulation test result for a leakage current of a commercial EMP power filter, and FIG. 12 is an exemplary view of a simulation test result for a leakage current of an EMP power filter according to an embodiment.

FIG. 11 and FIG. 12 are results of a simulation test for a current leaked through a ground line when commercial power is input, and the input of the filter is a commercial power signal of 230 V and 60 Hz based on the Korean standard.

Referring to FIG. 11, when the commercial power filter structure is applied, the leakage current is about 5 A.

In contrast, referring to FIG. 12, when the EMP power filter according to an embodiment is applied, the leakage current is equal to or lower than 1 A. Such a decrease in the leakage current results from applying components having lower capacity than existing ones to the L-C filter structure thanks to the dedicated surge protection circuit module M according to an embodiment.

According to the disclosed embodiment, an EMP power filter may be designed and produced using a smaller number of parts or lower capacity than existing products.

According to the disclosed embodiment, a decrease in the number of components and reduction of the capacity enable a lighter and smaller power filter to be produced, and a leakage current from the power filter can be decreased, whereby the power filter may be operated in a safer environment.

Although embodiments of the present disclosure have been described with reference to the accompanying drawings, those skilled in the art will appreciate that the present disclosure may be practiced in other specific forms without changing the technical spirit or essential features of the present disclosure. Therefore, the embodiments described above are illustrative in all aspects and should not be understood as limiting the present disclosure.

What is claimed is:

1. An Electromagnetic Pulse (EMP) power filter, comprising:
a varistor connected between an input terminal of a power line and a ground line;
first to fourth inductors connected in series from the input terminal of the power line;
a first feedthrough capacitor connected between the first inductor and the second inductor;
a second feedthrough capacitor connected between the third inductor and the fourth inductor; and
a dedicated surge protection circuit module having a first end connected between the second inductor and the third inductor and a second end connected to the ground line.

2. The EMP power filter of claim 1, wherein the dedicated surge protection circuit module includes
a low-frequency signal blocking unit for attenuating a magnitude of a power signal applied to the power line;
a surge signal switching unit for delivering a surge signal equal to or greater than a predetermined threshold through the ground line; and
a switching element protection unit for limiting a voltage and a current input to the surge signal switching unit.

3. The EMP power filter of claim 2, wherein the low-frequency signal blocking unit includes
a first capacitor having a first end connected to the power line; and
a second capacitor having a first end connected to the power line.

4. The EMP power filter of claim 3, wherein the surge signal switching unit includes a power transistor connected between an output terminal of the switching element protection unit, a second end of the second capacitor, and the ground line.

5. The EMP power filter of claim 4, wherein the power transistor is implemented as any one of an Insulated Gate Bipolar Transistor (IGBT), a Bipolar Junction Transistor (BJT), and a Field Effect Transistor (FET).

6. The EMP power filter of claim 4, wherein the surge signal switching unit further includes a third capacitor and a first resistor connected in parallel between the second end of the second capacitor and the ground line.

7. The EMP power filter of claim 4, wherein the surge signal switching unit further includes a third capacitor and a first resistor sequentially connected in series between the second end of the second capacitor and the ground line.

8. The EMP power filter of claim 4, wherein the switching element protection unit includes
a fourth capacitor connected to a second end of the first capacitor and the ground line;
a first diode connected to the second end of the first capacitor;
a second resistor and a Transient Voltage Suppressor (TVS) diode connected in parallel between a second end of the first diode and the ground line; and
a third resistor connected between the second end of the first diode and the power transistor.

9. The EMP power filter of claim 1, further comprising:
an additional dedicated surge protection circuit module having a first end connected between the third inductor and the second feedthrough capacitor and a second end connected to the ground line.

10. An Electromagnetic Pulse (EMP) power filter, comprising:
a first varistor connected between an input terminal of a first power line and a ground line;
first to fourth inductors connected in series from the input terminal of the first power line;
a first feedthrough capacitor connected between the first inductor and the second inductor;
a second feedthrough capacitor connected between the third inductor and the fourth inductor;
a first dedicated surge protection circuit module having a first end connected between the second inductor and the third inductor and a second end connected to the ground line;
a second varistor connected between an input terminal of a second power line and the ground line;
fifth to eighth inductors connected in series from the input terminal of the second power line;
a third feedthrough capacitor connected between the fifth inductor and the sixth inductor;
a fourth feedthrough capacitor connected between the seventh inductor and the eighth inductor;
a second dedicated surge protection circuit module having a first end connected between the sixth inductor and the seventh inductor and a second end connected to the ground line; and
a capacitor and a resistor connected in parallel, each having a first end connected between the first feedthrough capacitor and the second inductor and a second end connected between the third feedthrough capacitor and the sixth inductor.

11. The EMP power filter of claim 10, wherein at least one of the first dedicated surge protection circuit module, or the second dedicated surge protection circuit module, or a combination thereof includes
a low-frequency signal blocking unit for attenuating a magnitude of a power signal applied to the power line;
a surge signal switching unit for delivering a surge signal equal to or greater than a predetermined threshold through the ground line; and
a switching element protection unit for limiting a current and a voltage input to the surge signal switching unit.

12. The EMP power filter of claim 11, wherein the low-frequency signal blocking unit includes
a first capacitor having a first end connected to the power line; and
a second capacitor having a first end connected to the power line.

13. The EMP power filter of claim 12, wherein the surge signal switching unit includes a power transistor connected between an output terminal of the switching element protection unit, a second end of the second capacitor, and the ground line.

14. The EMP power filter of claim 13, wherein the surge signal switching unit further includes a third capacitor and a first resistor connected in parallel between the second end of the second capacitor and the ground line.

15. The EMP power filter of claim 13, wherein the surge signal switching unit further includes a third capacitor and a first resistor sequentially connected in series between the second end of the second capacitor and the ground line.

16. The EMP power filter of claim 13, wherein the switching element protection unit includes
a fourth capacitor connected to a second end of the first capacitor and the ground line;
a first diode connected to the second end of the first capacitor;
a second resistor and a Transient Voltage Suppressor (TVS) diode connected in parallel between a second end of the first diode and the ground line; and
a third resistor connected between the second end of the first diode and the power transistor.

17. A dedicated high-power surge protection circuit device, which is connected between elements constituting an L-C filter of an Electromagnetic Pulse (EMP) power filter, comprising:
a low-frequency signal blocking unit for attenuating a magnitude of a power signal applied to a power line;
a surge signal switching unit for delivering a surge signal equal to or greater than a predetermined threshold through a ground line; and
a switching element protection unit for limiting a voltage and a current input to the surge signal switching unit.

18. The dedicated high-power surge protection circuit device of claim 17, wherein the low-frequency signal blocking unit includes
a first capacitor having a first end connected to the power line; and
a second capacitor having a first end connected to the power line.

19. The dedicated high-power surge protection circuit device of claim 18, wherein the surge signal switching unit includes
a power transistor connected between an output terminal of the switching element protection unit, a second end of the second capacitor, and the ground line; and
a third capacitor and a first resistor connected in parallel or series between the second end of the second capacitor and the ground line.

20. The dedicated high-power surge protection circuit device of claim 19, wherein the switching element protection unit includes
a fourth capacitor connected to a second end of the first capacitor and the ground line;
a first diode connected to the second end of the first capacitor;
a second resistor and a Transient Voltage Suppressor (TVS) diode connected in parallel between a second end of the first diode and the ground line; and
a third resistor connected between the second end of the first diode and the power transistor.
